(19) United States
(12) Patent Application Publication
(10) Pub. No.: US 2025/0201527 A1
(43) Pub. Date: Jun. 19, 2025

(54) High Conformal Coating on Textured Surface of Processing Chamber Component

(71) Applicant: Applied Materials, Inc., Santa Clara, CA (US)

(72) Inventors: Cheng-Hsuan CHOU, Mountain View, CA (US); Yixing LIN, Saratoga, CA (US)

(21) Appl. No.: 18/389,591

(22) Filed: Dec. 19, 2023

(51) Int. Cl. H01J 37/32

(52) U.S. Cl. CPC H01J 37/32477

(57) ABSTRACT

A plasma processing chamber component in which a body has an upper body surface with a plurality of underlay texture features disposed therein having a first room mean square (RMS) surface roughness; and a conformal layer disposed over the upper body surface forming an upper component surface having a second RMS surface roughness which is greater than or equal to about 90% of the first RMS surface roughness.

### FIELD

Embodiments of the present disclosure generally relate to a chamber component to be used in plasma processing chambers for semiconductor processing.

### BACKGROUND

A plasma processing chamber may be used to process a substrate in an energized process gas, such as a plasma, to manufacture semiconductor substrates such as integrated circuit chips and the like. The processing chamber includes a process zone bound by walls and other structures, and including various components into which a process gas is introduced, a gas energizer to energize the process gas, and an exhaust system to exhaust and control the pressure of the process gas in the chamber. The processing chamber may, for example, be used to deposit a material on a substrate, which can also deposit on chamber components within the process chamber, such as the inner surfaces of a chamber sidewall, ceiling, liner, deposition ring, and/or the like. This material inadvertently deposited on chamber components can peel away from, or otherwise dislodge or flake off of chamber components to form unwanted or extraneous particles in the chamber contaminating the substrate being processed.

There is a need for an improved chamber component which prevents or otherwise minimizes the spurious shedding or flaking off of materials deposited thereon.

### SUMMARY

Chamber components having a high conformal coating layer disposed on a top of a textured surface are provided herein, along with methods of forming such chamber component. The coating layer provides strong adhesion and larger surface area for materials deposited in a substrate processing chamber which reduces material peeling off from the chamber component.

In embodiments, a plasma processing chamber component comprises a body having an upper body surface comprising a plurality of underlay texture features disposed therein, and having a first RMS surface roughness from about 150 micrometers to about 1500 micrometers; and a conformal layer disposed over the upper body surface forming an upper component surface having a second RMS surface roughness, wherein the second RMS surface roughness is greater than or equal to about 90% of the first RMS surface roughness.

In embodiments, a plasma processing chamber comprises a chamber enclosure; and a plasma processing chamber component disposed in the chamber enclosure; the plasma processing chamber component comprising a body having an upper body surface comprising a plurality of underlay texture features disposed therein, and having a first RMS surface roughness from about 150 micrometers to about 1500 micrometers; and a conformal layer disposed over the upper body surface comprising aluminum oxide, titanium oxide, or a combination thereof forming an upper component surface having a second RMS surface roughness and a porosity of less than or equal to about 5%, wherein the second RMS surface roughness is greater than or equal to about 90% of the first RMS surface roughness.

In embodiments, a plasma processing chamber component comprises a body having an upper body surface comprising a plurality of underlay texture features disposed into the body using an electron beam, comprising a plurality of peaks separated by valleys having an average depth of about 150 micrometers to 1500 micrometers and an average peak-to-peak separation distance of about 100 micrometers to 500 micrometers such that the upper body surface has a first RMS surface roughness; and a conformal layer disposed over the upper body surface comprising aluminum oxide, titanium oxide, or a combination thereof forming an upper component surface, wherein the conformal layer has an average thickness of about 40 micrometers to 500 micrometers, a uniform thickness of +/−10% of the average thickness, and a porosity of less than or equal to about 2%, such that the upper component surface has a second RMS surface roughness which is greater than or equal to about 90% of the first RMS surface roughness.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic cross-sectional side view of a PVD chamber.

FIG. 2 is a cross-sectional side view of a chamber component having a conformal coating layer according to embodiments disclosed herein.

FIG. 3 is a cross-sectional side view of a portion of a chamber component having an alternative conformal coating layer according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments include a component of a substrate processing chamber, also referred to herein simply as a “chamber component”, having a high conformal coating layer disposed on a top of a textured surface having a strong adhesion and larger surface area for materials deposited in a substrate processing chamber. This high conformal coating reduces material previously deposited on the surface from peeling off or otherwise being dislodged from the surface of the chamber component during substrate processing.

As used herein, root mean square roughness (RMS roughness), refers to a dispersion parameter characterizing the surface roughness, obtained by squaring each height value of a measured surface in the dataset, then taking the square root of the mean. For purposes herein, RMS roughness may be determined with a contact or an optical profilometer according to accepted methods and practices in the art.

In embodiments, a chamber component comprises a body having an upper body surface comprising a plurality of underlay texture features disposed therein, and having a first RMS surface roughness; and a conformal layer disposed over the upper body surface forming an upper component surface having a second RMS surface roughness, wherein the second RMS surface roughness is greater than or equal to about 90% of the first RMS surface roughness. In embodiments, the conformal layer disposed over the upper body surface comprises aluminum oxide, titanium oxide, tungsten oxide, or a combination thereof. In embodiments, the conformal layer disposed over the upper body surface has a porosity of less than or equal to about 5%. In embodiments, the first RMS surface roughness and the second RMS surface roughness are individually about 150 micrometers to about 1500 micrometers.

In embodiments, the plurality of underlay texture features of the body comprise a plurality of peaks separated by valleys, which in embodiments have an average depth of about 150 micrometers to 1500 micrometers, and an average peak-to-peak separation distance of about 100 micrometers to 500 micrometers.

In embodiments, the conformal layer has an average thickness of about 40 micrometers to 500 micrometers. In embodiments the conformal layer has a uniform thickness of +/−10% of the average thickness.

In embodiments, a linear temperature expansion coefficient of the conformal layer is about 45% to 110% of a linear temperature expansion coefficient of the body, e.g., of the material from which the processing chamber component or assembly is made. In embodiments, the conformal layer comprises aluminum oxide, titanium oxide, or a combination thereof. In embodiments, the conformal layer comprises aluminum oxide. In embodiments, the conformal layer comprises titanium oxide. In embodiments, the conformal layer consists essentially of aluminum oxide. In embodiments, the conformal layer consists essentially of titanium oxide.

In embodiments, the conformal layer comprises a first layer of aluminum metal disposed on an upper surface of the body, which is arranged between the upper body surface and a second layer of aluminum oxide.

In embodiments, the conformal layer has a porosity of less than or equal to about 2%. In embodiments, the conformal layer is formed by plasma spray. In embodiments, the body of the chamber component is formed from a stainless steel, titanium, or aluminum.

In embodiments, the plurality of underlay texture features on the upper surface of the chamber component body are disposed into the body using an electron beam.

In embodiments, a plasma processing chamber comprises a chamber enclosure, comprising a plasma processing chamber component disposed within the chamber enclosure according to one or more embodiments disclosed herein.

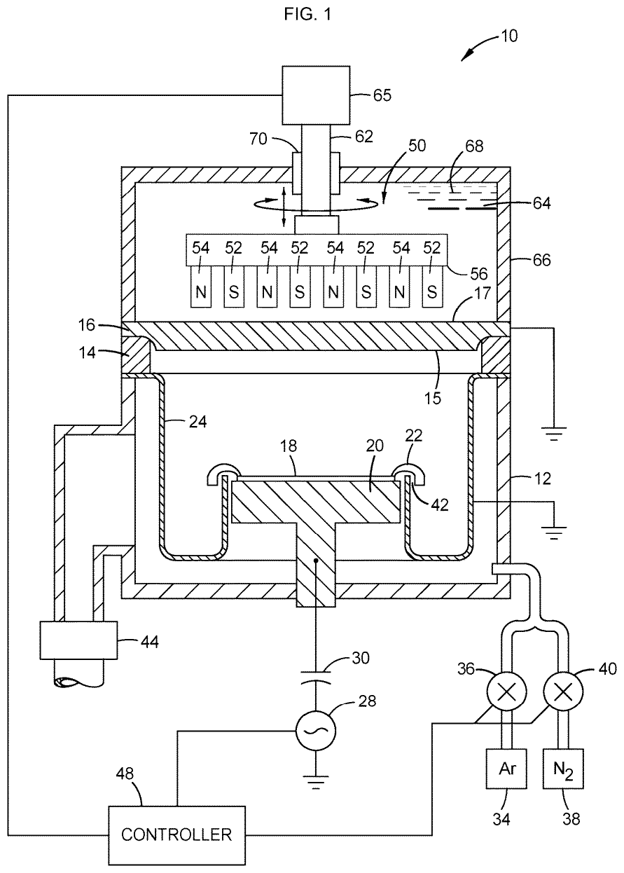

FIG. 1 is a schematic cross-sectional side view of a substrate processing chamber 10, which in this case is a PVD chamber. The chamber 10 includes a vacuum chamber body 12 sealed through a ceramic insulator 14 to a sputtering target 16. The target 16 has at least a first surface 15 facing a substrate 18 and a second surface 17 opposite the first surface 15. The first surface 15 of the target 16 is composed of a material to be sputter deposited onto a surface of the substrate 18 disposed on a substrate support 20 disposed in the chamber body 12. The substrate 18 may be secured by a substrate clamp 22. Alternatively to the substrate clamp 22, a cover ring or an electrostatic chuck may be incorporated into the substrate support 20 for securing the substrate 18. Examples of target materials include carbon, aluminum, copper, titanium, tantalum, cobalt, tungsten, nickel, molybdenum, alloys of these metals containing an alloying element, or other material, metals and/or metal alloys amenable to DC sputtering. However, it is to be understood that other forms of sputtering, e.g., RF sputtering and the like, as well as other forms of depositions, e.g., plasma enhanced PVD (PE-PVD), CVD PE-CVD, ALD, PE-ALD, and/or the like, may be used to deposit material onto the substrate.

A grounded shield 24 is disposed within the chamber body 12 for protecting the chamber body 12 from the sputtered material. The shield 24 also provides a grounded anode. An RF power supply 28 may be coupled to an electrode (not shown) embedded in the substrate support 20 through an AC capacitive coupling circuit 30 to allow the substrate support 20 to develop a DC self-bias voltage in the presence of a plasma. A negative DC self-bias attracts positively charged sputter ions created in a high-density plasma deeply into a high aspect-ratio holes characteristic of advanced integrated circuits.

A first gas source 34 supplies a working gas, such as argon, to the chamber body 12 through a mass flow controller 36. In some embodiments, a second gas source 38 or a plurality of gas sources may be utilized to supply one or more additional gases, such as nitrogen gas, and/or a reactive gas, to the chamber body 12. The gases can be introduced from various positions within the chamber body 12. For example, one or more inlet pipes located near the bottom of the chamber body 12 supply gas at the back of the shield 24. The gas penetrates through an aperture at the bottom of the shield 24 or through a gap 42 formed between the substrate clamp 22 and the shield 24. A vacuum pumping system 44 connected to the chamber body 12 through a wide pumping port maintains the interior of the chamber body 12 at a low pressure. A computer based controller 48 controls components of the chamber 10 including the RF power supply 28 and the mass flow controllers 36, 40.

To provide efficient sputtering, a magnetron 50 is disposed above the target 16. The magnetron 50 may be disposed in a magnetron cavity 64 defined by a coolant chamber 66 positioned above the target 16. The magnetron 50 includes a plurality of magnets 52, 54 to produce a magnetic field within the chamber body 12. The plurality of magnets 52, 54 may be coupled by a backing plate 56. Each magnet 52 may be arranged so one pole is facing the target 16, and each magnets 54 may be arranged so the other pole is facing the target 16. For example, as shown in FIG. 1, each magnet 52 is arranged so the south pole is facing the target 16, and each magnet 54 is arranged so the north pole is facing the target 16. The magnets 52 and magnets 54 may be alternately arranged along a longitudinal dimension (in the X-axis direction) of the magnetron 50, as shown in FIG. 1. In some embodiments, a pair of adjacent magnets 52, 54 may be replaced with a single U shaped magnet, and the magnetron 50 includes a plurality of U shaped magnets. The magnetron 50 is coupled to a shaft 62 driven by a motor 65. The motor 65 may be also capable of moving the magnetron 50 along the Z-axis and rotate about the shaft 62.

To counteract the large amount of power delivered to the target 16, the back of the target 16 may be sealed to the coolant chamber 66, which encloses the magnetron cavity 64. The coolant chamber 66 may include a coolant 68, such as chilled deionized water, to cool the target 16 and/or magnetron 50. The magnetron 50 is immersed in the coolant 68, and the shaft 62 passes through the coolant chamber 66 through a rotary seal 70.

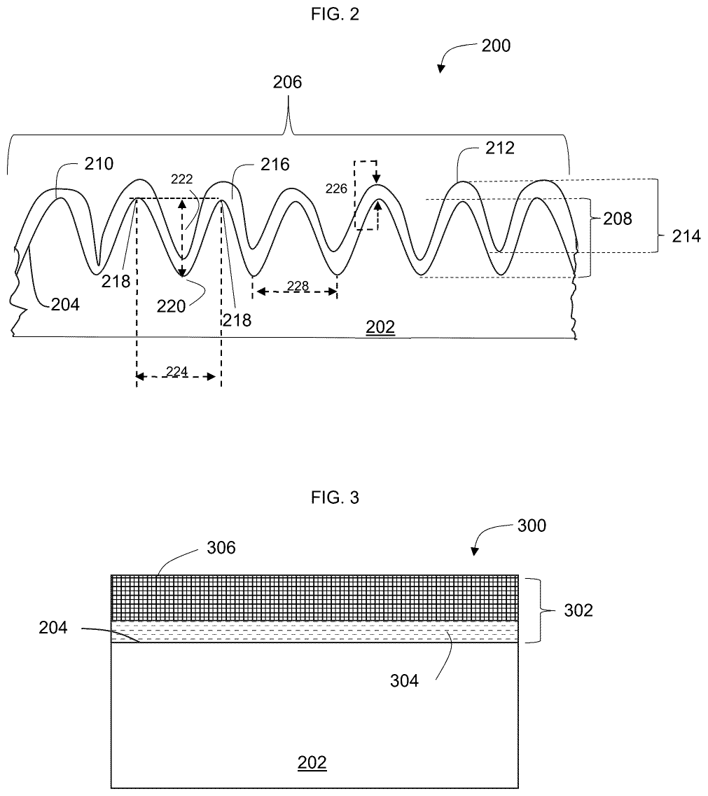

FIG. 2 is a schematic cross-sectional side view of a chamber component 200 having an underlay body 202 having an upper body surface 204 comprising a plurality of underlay texture features 206 disposed therein. The underlay texture features 206 resulting in the upper body surface 204 having a first RMS surface roughness 208. In embodiments, the conformal layer 210 is disposed over and directly on the upper body surface 204. In embodiments, the conformal layer 210 comprises aluminum oxide, titanium oxide, or a combination. The conformal layer 210 is highly conformal to the underlay texture features 206 such that the conformal layer 210 forms an upper component surface 212 having a second RMS surface roughness 214 which is greater than or equal to about 90% of the first RMS surface roughness. In embodiments, conformal layer 210 has a porosity 216 of less than or equal to about 5%.

In embodiments, the first RMS surface roughness 208 and/or the second RMS surface roughness 214 are each individually from about 150 micrometers to about 1500 micrometers. In embodiments, the first RMS surface roughness 208 and/or the second RMS surface roughness 214 are each individually greater than or equal to about 200 micrometers, or greater than or equal to about 400 micrometers, or greater than or equal to about 500 micrometers, or greater than or equal to about 700 micrometers, or greater than or equal to about 900 micrometers, or greater than or equal to about 1000 micrometers, and less than or equal to about 1200 micrometers or less than or equal to about 1500 micrometers.

In embodiments, the plurality of underlay texture features 206 of the body 202 comprise a plurality of peaks 218 separated by valleys 220 (only one is labeled for clarity). In embodiments, the valleys 220 have an average depth 222 (determined from the top of the peaks 218) from about 150 micrometers to about 1500 micrometers. In embodiments, the average depth 222 of the valleys 220 is greater than or equal to about 200 micrometers, or greater than or equal to about 400 micrometers, or greater than or equal to about 500 micrometers, or greater than or equal to about 700 micrometers, or greater than or equal to about 900 micrometers, or greater than or equal to about 1000 micrometers, and less than or equal to about 1200 micrometers or less than or equal to about 1500 micrometers. In embodiments, the average peak-to-peak separation distance 224 and the average width of the peaks 228 is from about 100 micrometers to 1500 micrometers.

In embodiments, the conformal layer 210 has an average thickness 226 from about 40 micrometers to 500 micrometers, which in embodiments is greater than or equal to about 50 micrometers, or greater than or equal to about 85 micrometers, or greater than or equal to about 100 micrometers, or, greater than or equal to about 200 micrometers, or greater than or equal to about 300 micrometers, and less than or equal to about 400 micrometers or less than or equal to about 500 micrometers. In embodiments, the conformal layer 210 has a uniform thickness of +/−10%, or +/−7%, or +/−5% of the average thickness 226.

In embodiments, the conformal layer 210 has a porosity 216, i.e., pores or discontinuities disposed into the layer, of less than or equal to about 2%, or less than or equal to about 1%, or less than or equal to about 0.5%.

In embodiments, the conformal layer comprises material selected for having a linear temperature expansion coefficient which is from about 45% to 110% the linear temperature expansion coefficient of the material from which the body is formed. In embodiments, the conformal layer comprises material selected for having a linear temperature expansion coefficient which is greater than or equal to about 50%, or greater than or equal to about 70%, or greater than or equal to about 90%, or essentially equal to linear temperature expansion coefficient of the material from which the body is formed, and less than or equal to about 105% or less than or equal to about 110% of the linear temperature expansion coefficient of the material from which the body is formed.

In embodiments, the conformal layer 210 comprises, or consists essentially of, or consists of aluminum oxide. In embodiments, the conformal layer 210 comprises, or consists essentially of, or consists of titanium oxide.

FIG. 3 depicts a section of a plasma processing chamber component 300 having an alternative conformal layer 302, comprising a first layer of aluminum metal 304 disposed between the upper body surface 204 and a second layer of aluminum oxide 306.

In embodiments, the body 202 is formed from a stainless steel, e.g., an stainless steel, an austinite steel, and the like, titanium or an alloy comprising titanium, and/or aluminum or an alloy comprising aluminum. In embodiments, the conformal layer is formed by plasma spray.

In embodiments, the plurality of underlay texture features 206 may be formed by any suitable method, such as grit blast. In embodiments, the plurality of underlay texture features 206 are formed using an electron beam. In embodiments, the underlay texture features are formed by moving an electromagnetic beam to a first region of a surface and scanning the electromagnetic beam across the first region of surface to heat the surface, and scanning the electromagnetic beam across the heated surface of the first region to form the underlay texture feature comprising peaks, valleys, depressions, protuberances, and combinations thereof. (see for example, US20100108641A1 and US20210183657A1, and U.S. Pat. No. 11,251,024B2, the disclosures of which are fully incorporated by reference herein).

### Exemplary Embodiments

Embodiments of the instant application include, but are not limited to:
E1. A plasma processing chamber component, comprising: a body having an upper body surface comprising a plurality of underlay texture features disposed therein, and having a first room mean square (RMS) surface roughness; and a conformal layer disposed over the upper body surface forming an upper component surface having a second RMS surface roughness, wherein the second RMS surface roughness is greater than or equal to about 90% of the first RMS surface roughness.
E2. The plasma processing chamber component according to embodiment E1, wherein the conformal layer disposed over the upper body surface comprises aluminum oxide, titanium oxide, tungsten oxide, or a combination thereof.
E3. The plasma processing chamber component according to any of embodiments E1-E2, wherein the first RMS surface roughness and the second RMS surface roughness are individually about 150 micrometers to about 1500 micrometers.
E4. The plasma processing chamber component according to any of embodiments E1-E3, wherein the plurality of underlay texture features of the body comprise a plurality of peaks separated by valleys having an average depth of about 150 micrometers to 1500 micrometers, and an average peak-to-peak separation distance of about 100 micrometers to 1500 micrometers.
E5 The plasma processing chamber component according to any of embodiments E1-E4, wherein the conformal layer has an average thickness of about 40 micrometers to 500 micrometers, and a uniform thickness of +/−10% of the average thickness.
E6. The plasma processing chamber component according to any of embodiments E1-E5, wherein a linear temperature expansion coefficient of the conformal layer is about 45% to 110% of a linear temperature expansion coefficient of the body.
E7 The plasma processing chamber component according to any of embodiments E1-E6, wherein the conformal layer consists essentially of aluminum oxide.
E8. The plasma processing chamber component according to any of embodiments E1-E7, wherein the conformal layer consists essentially of titanium oxide.
E9. The plasma processing chamber component according to any of embodiments E1-E8, wherein the conformal layer consists essentially of aluminum oxide.
E10. The plasma processing chamber component according to any of embodiments E1-E9, wherein the conformal layer comprises a first layer of aluminum metal disposed between the upper body surface and a second layer of aluminum oxide.
E11. The plasma processing chamber component according to any of embodiments E1-E10, wherein the conformal layer has a porosity of less than or equal to about 5%.
E12. The plasma processing chamber component according to any of embodiments E1-E11, wherein the conformal layer is formed by plasma spray.
E13. The plasma processing chamber component according to any of embodiments E1-E12, wherein the plurality of underlay texture features are disposed into the body using an electron beam.
E14. A plasma processing chamber, comprising:
a chamber enclosure; and
a plasma processing chamber component disposed in the chamber enclosure;
the plasma processing chamber component comprising:
a body having an upper body surface comprising a plurality of underlay texture features disposed therein, and having a first RMS surface roughness; and
a conformal layer disposed over the upper body surface comprising aluminum oxide, titanium oxide, tungsten oxide, or a combination thereof forming an upper component surface having a second RMS surface roughness and a porosity of less than or equal to about 5%, wherein the second RMS surface roughness is greater than or equal to about 90% of the first RMS surface roughness.
E15. The plasma processing chamber component according to embodiment E14, wherein the underlay texture features of the body comprise a plurality of peaks separated by valleys having an average depth of about 150 micrometers to 1500 micrometers, and an average peak-to-peak separation distance of about 100 micrometers to 500 micrometers.
E16. The plasma processing chamber component according to any of embodiments E14-E15, wherein the conformal layer has an average thickness of about 40 micrometers to 500 micrometers, and a uniform thickness of +/−10% of the average thickness.
E17. The plasma processing chamber component according to any of embodiments E14-E16, wherein a linear temperature expansion coefficient of the conformal layer is about 45% to 110% of a linear temperature expansion coefficient of the body.
E18. The plasma processing chamber component according to any of embodiments E14-E17, wherein the conformal layer consists essentially of aluminum oxide.
E19. The plasma processing chamber component according to any of embodiments E14-E17, wherein the conformal layer consists essentially of titanium oxide.
E20. The plasma processing chamber component according to any of embodiments E14-E17, wherein the conformal layer consists essentially of tungsten oxide.
E21. The plasma processing chamber component according to any of embodiments E14-E20, wherein the conformal layer has a porosity of less than or equal to about 2%.
E22. The plasma processing chamber component according to any of embodiments E14-E21, wherein the plasma processing chamber component is a shield, a clamp, or a substrate support.
E23. A plasma processing chamber component, comprising:
a body having an upper body surface comprising a plurality of underlay texture features disposed into the body using an electron beam, comprising a plurality of peaks separated by valleys having an average depth of about 150 micrometers to 1500 micrometers and an average peak-to-peak separation distance of about 100 micrometers to 500 micrometers such that the upper body surface has a first RMS surface roughness; and
a conformal layer disposed over the upper body surface comprising aluminum oxide, titanium oxide, or a combination thereof forming an upper component surface, wherein the conformal layer has an average thickness of about 40 micrometers to 500 micrometers, a uniform thickness of +/−10% of the average thickness, and a porosity of less than or equal to about 2%, such that the upper component surface has a second RMS surface roughness which is greater than or equal to about 90% of the first RMS surface roughness.

While the foregoing is directed to embodiments of the present disclosure, other and further embodiments of the disclosure may be devised without departing from the basic scope thereof.

1. A plasma processing chamber component, comprising:
a body having an upper body surface comprising a plurality of underlay texture features disposed therein, and having a first room mean square (RMS) surface roughness of about 150 micrometers to about 1500 micrometers; and
a conformal layer disposed over the upper body surface forming an upper component surface having a second RMS surface roughness, wherein the second RMS surface roughness is greater than or equal to about 90% of the first RMS surface roughness.

2. The plasma processing chamber component of claim 1, wherein the conformal layer disposed over the upper body surface comprises aluminum oxide, titanium oxide, tungsten oxide, or a combination thereof.

3. The plasma processing chamber component of claim 1, wherein the first RMS surface roughness and the second RMS surface roughness are individually about 180 micrometers to about 1000 micrometers.

4. The plasma processing chamber component of claim 1, wherein the plurality of underlay texture features of the body comprise a plurality of peaks separated by valleys having an average depth of about 150 micrometers to 1500 micrometers, and an average peak-to-peak separation distance of about 100 micrometers to 1500 micrometers.

5. The plasma processing chamber component of claim 1, wherein the conformal layer has an average thickness of about 40 micrometers to 500 micrometers, and a uniform thickness of +/−10% of the average thickness.

6. The plasma processing chamber component of claim 1, wherein a linear temperature expansion coefficient of the conformal layer is about 45% to 110% of a linear temperature expansion coefficient of the body.

7. The plasma processing chamber component of claim 1, wherein the conformal layer consists essentially of aluminum oxide.

8. The plasma processing chamber component of claim 1, wherein the conformal layer consists essentially of titanium oxide.

9. The plasma processing chamber component of claim 1, wherein the conformal layer comprises a first layer of aluminum metal disposed between the upper body surface and a second layer of aluminum oxide.

10. The plasma processing chamber component of claim 1, wherein the conformal layer has a porosity of less than or equal to about 5%.

11. The plasma processing chamber component of claim 1, wherein the conformal layer is formed by plasma spray.

12. The plasma processing chamber component of claim 1, wherein the plurality of underlay texture features are disposed into the body using an electron beam.

13. A plasma processing chamber, comprising:
a chamber enclosure; and
a plasma processing chamber component disposed in the chamber enclosure;
the plasma processing chamber component comprising:
a body having an upper body surface comprising a plurality of underlay texture features disposed therein, and having a first RMS surface roughness of about 150 micrometers to about 1500 micrometers; and
a conformal layer disposed over the upper body surface comprising aluminum oxide, titanium oxide, tungsten oxide, or a combination thereof forming an upper component surface having a second RMS surface roughness and a porosity of less than or equal to about 5%, wherein the second RMS surface roughness is greater than or equal to about 90% of the first RMS surface roughness.

14. The plasma processing chamber of claim 13, wherein the plurality of underlay texture features of the body comprise a plurality of peaks separated by valleys having an average depth of about 150 micrometers to 1500 micrometers, and an average peak-to-peak separation distance of about 100 micrometers to 500 micrometers.

15. The plasma processing chamber of claim 13, wherein the conformal layer has an average thickness of about 40 micrometers to 500 micrometers, and a uniform thickness of +/−10% of the average thickness.

16. The plasma processing chamber of claim 13, wherein a linear temperature expansion coefficient of the conformal layer is about 45% to 110% of a linear temperature expansion coefficient of the body.

17. The plasma processing chamber of claim 13, wherein the conformal layer consists essentially of aluminum oxide.

18. The plasma processing chamber of claim 13, wherein the conformal layer has a porosity of less than or equal to about 2%.

19. The plasma processing chamber of claim 13, wherein the plasma processing chamber component is a shield, a clamp, or a substrate support.

20. A plasma processing chamber component, comprising:
a body having an upper body surface comprising a plurality of underlay texture features disposed into the body using an electron beam, comprising a plurality of peaks separated by valleys having an average depth of about 150 micrometers to 1500 micrometers and an average peak-to-peak separation distance of about 100 micrometers to 500 micrometers such that the upper body surface has a first RMS surface roughness; and
a conformal layer disposed over the upper body surface comprising aluminum oxide, titanium oxide, or a combination thereof forming an upper component surface, wherein the conformal layer has an average thickness of about 40 micrometers to 500 micrometers, a uniform thickness of +/−10% of the average thickness, and a porosity of less than or equal to about 2%, such that the upper component surface has a second RMS surface roughness which is greater than or equal to about 90% of the first RMS surface roughness.
